(19) United States
(12) Patent Application Publication
(10) Pub. No.: US 2004/0029373 A1
(43) Pub. Date: Feb. 12, 2004

(54) Method of manufacturing semiconductor device

(75) Inventor: Kenji Yoshiyama, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/339,291

(22) Filed: Jan. 10, 2003

(30) Foreign Application Priority Data
Aug. 8, 2002 (JP) 2002-231008

(51) Int. Cl. H01L 21/8234; H01L 21/3205; H01L 21/4763

(52) U.S. Cl. 438/592

(57) ABSTRACT

A first SP film (6) and a second SP film (7) are formed in this order on a semiconductor substrate (1) so as to cover gate structures (10) on the semiconductor substrate (1) in a silicide region. The second SP film (7) on the semiconductor substrate (1) in the silicide region is then removed using the first SP film (6) as an etching stopper. Next, the first SP film (6) in the silicide region is removed, and thereafter, salicidation is implemented. Since an SP film of two-layered structure composed of the first SP film (6) and second SP film (7) is formed on the semiconductor substrate (1) in an SP region, a silicide film is not formed thereon.

### BACKGROUND OF THE INVENTION

1. Field of the Invention

The present invention relates to a method of manufacturing a semiconductor device having a silicide protection film.

2. Description of the Background Art

FIGS. 9 through 12 are sectional views showing a method of manufacturing a conventional semiconductor device in sequential order of steps. First, as shown in FIG. 9, an element isolating insulation film 102 is formed in the upper surface of a semiconductor substrate 101, which is a p-type silicon substrate, for example, by well-known LOCOS (local oxidation of silicon) or trench isolation. The element isolating insulation film 102 is formed of, e.g., a silicon oxide film, and divides the semiconductor substrate 101 into a silicide region on which a silicide film is to be provided and a silicide protection region (hereinafter referred to as “SP region”) on which the silicide film is not to be provided. The semiconductor substrate 101 in the SP region is used as a resistor, for example.

Next, a plurality of gate structures 110 are formed at predetermined intervals on the semiconductor substrate 101 in the silicide region. Each gate structure 110 includes a gate insulation film 103 formed of e.g., a silicon oxide film, a gate electrode 105 formed of e.g., a polysilicon film and sidewalls 104. The sidewalls 104 each have a two-layered structure composed of, for example, a TEOS (tetraethyl orthosilicate) film 104a and a silicon nitride film 104b.

A method of forming each gate structure 110 will be described in detail. First, a silicon oxide film and a polysilicon film are formed on the entire surface in this order. Then, a resist having a predetermined opening pattern is provided on the polysilicon film, and the polysilicon film is etched using the resist as a mask until the silicon oxide film is exposed. Accordingly, the gate insulation film 103 and gate electrode 105 are formed in this order on the semiconductor substrate 101 in the silicide region. Impurities such as phosphor or arsenic are ion-implanted at a relatively low concentration into the upper surface of the semiconductor substrate 101 in the silicide region using the gate insulation film 103 and gate electrode 105 as a mask. Accordingly, an n⁻ type impurity region 109a is formed in the upper surface of the semiconductor substrate 101 in the silicide region.

Next, a TEOS film and a silicon nitride film are formed on the entire surface in this order, and are then etched by anisotropic dry etching whose etch rate increases in the depth direction of the semiconductor substrate 101. Accordingly, the sidewalls 104 each including the TEOS film 104a and silicon nitride film 104b are formed on side faces of the gate insulation film 103 and gate electrode 105, whereby formation of the gate structure 110 is completed. At two gate structures 110 adjacent to each other, l, the distance between a side face of one of the two gate structures 110 and that of the other of the two gate structures 110 opposed to each other is set at 100 nm, for example. That is, the distance l between the surface of a sidewall 104 of the one of the two gate structures 110 and that of a sidewall 104 of the other of the two gate structures 110 opposed to each other is set at 100 nm, for example. Hereinafter, at two gate structures adjacent to each other, the distance between a side face of one of the two gate structures and that of the other of the two gate structures opposed to each other will simply be referred to as “distance between gate structures”.

Impurities such as phosphor or arsenic are ion-implanted at a relatively high concentration into the upper surface of the semiconductor substrate 101 in the silicide region using the gate structures 110 as a mask. Accordingly, an n⁺ type impurity region 109b is formed in the upper surface of the semiconductor substrate 101 in the silicide region.

Through the above-described steps, a source/drain region 109 including the n⁻ type impurity region 109a and n⁺ type impurity region 109b is formed in the upper surface of the semiconductor substrate 101 in the silicide region. Accordingly, formation of a plurality of transistors at the semiconductor substrate 101 in the silicide region is completed.

Next, a silicide protection film (hereinafter referred to as “SP film”) 106 is formed over the semiconductor substrate 101 in the silicide region and SP region and over the element isolating insulation film 102 so as to cover the gate structures 110. An NSG (non-doped silicate glass) film, for example, is used for the SP film 106. At this time, the SP film 106 is set to have a film thickness m of such a value that is not removed by wet processes to be performed in forming a silicide film 108 which will be described later. Here, the film thickness m is set at 100 nm, for example.

Next, as shown in FIG. 10, a resist 107 is formed on the SP film 106 on the semiconductor substrate 101 in the SP region, while exposing the SP film 106 on the semiconductor substrate 101 in the silicide region and on part of the element isolating insulation film 102. Then, as shown in FIG. 11, the SP film 106 is etched using the resist 107 as a mask. Accordingly, the SP film 106 on the semiconductor substrate 101 in the silicide region and on part of the element isolating insulation film 102 is removed.

Next, the resist 107 is removed, and a cobalt film is formed on the entire surface by sputtering, for example. Then, heat treatment is conducted using a lamp anneal system, for example, to cause cobalt to react with silicon in contact therewith. Accordingly, the upper surface of the semiconductor substrate 101 in the silicide region is silicided, whereby the silicide film 108 is formed. At the same time, the upper surface of the gate electrode 105 of each gate structure 110 is silicided, whereby the silicide film 108 is formed. Thereafter, an unreacted part of the cobalt film is removed, thereby obtaining the structure shown in FIG. 12. Since the SP film 106 is formed on the semiconductor substrate 101 in the SP region, silicidation is not performed, and hence, the silicide film 108 is not formed. In forming the silicide film 108, a plurality of wet processes are usually performed.

As has been described, according to the method of manufacturing the conventional semiconductor device, the SP film 106 is provided in a region (SP region) where a silicide film is not desired to be formed, preventing a silicide film from being formed in the region.

According to the method of manufacturing the conventional semiconductor device as described above, the SP film 106 is formed in one layer. Further, the film thickness m of the SP film 106 is set at such a value that is not removed by the wet process to be performed in forming the silicide film 108. This means that the film thickness m of the SP film 106 cannot be reduced unless the method of forming the silicide film 108 is changed. Therefore, as the distance l between the gate structures 110 decreases with miniaturization of the semiconductor device, the film thickness m of the SP film 106 increases as compared to the distance l between the gate structures 110. Thus, in the aforementioned case where the distance l between the gate structures 110 and the film thickness m of the SP film 106 are each set at 100 nm, the SP film 106 is not conformal to the underlying structure, and the upper surface of the SP film 106 on the semiconductor substrate 101 in the silicide region becomes almost flat, as shown in FIG. 9. That is, thickness t2 of the SP film 106 positioned on the semiconductor substrate 101 between two gate structures 110 adjacent to each other is greater than thickness t1 of the SP film 106 on the gate electrode 105. The thickness t1 of the SP film 106 on the gate electrode 105 is identical to the set film thickness m of the SP film 106.

As described, in the case where the distance l between the gate structures 110 decreases with miniaturization of the semiconductor device, causing the thickness t2 of the SP film 106 between the gate structures 110 to be greater than the thickness t1 of the SP film 106 positioned on the gate electrode 105, setting of etching time in accordance with the thickness t1 of the SP film 106 on the gate electrode 105 might cause the SP film 106 between the gate structures 110 to remain without being completely removed, as shown in FIG. 11. This may cause a drawback such as that the silicide film 108 is not formed on the semiconductor substrate 101 between the gate structures 110, as shown in FIG. 12.

On the other hand, in the case where the SP film 106 is etched by anisotropic etching with etching time being in accordance with the thickness t2 of the SP film 106 between the gate structures 110 in order to completely remove the SP film 106 between the gate structures 110, part of the element isolating insulation film 102 that is not covered by the resist 107 as shown at portion A in FIG. 13 may excessively be etched, which in turn degrades the semiconductor device in junction leak characteristic.

Alternatively, in the case where the SP film 106 is etched by isotropic etching with etching time being in accordance with the thickness t2 of the SP film 106 between the gate structures 110 in order to completely remove the SP film 106 between the gate structures 110, the TEOS film 104a of the sidewall 104 is etched as shown at portion B in FIG. 14. This may cause the silicide film 108 to be formed even under the silicon nitride film 104b of the sidewall 104, which in turn degrades transistor characteristics. Even in this case, as shown at portion C in FIG. 14, part of the element isolating insulation film 102 that is not covered by the resist 107 may excessively be etched and the gate electrode 105 may be etched, which in turn degrades the semiconductor device in performance. Of course, performing anisotropic etching and isotropic etching in combination will not overcome the above-described drawbacks.

### SUMMARY OF THE INVENTION

An object of the present invention is to provide a reliable technique capable of removing an SP film provided on a semiconductor substrate in a region where a silicide film is to be formed while suppressing degradation of a semiconductor device in performance even in the case where the distance between gate structures decreases with miniaturization of the semiconductor device.

The present invention is directed to a method of manufacturing a semiconductor device, including the following steps (a) through (g). The step (a) is to prepare a semiconductor substrate having first and second regions. The step (b) is to form first and second gate structures at a predetermined interval therebetween on the semiconductor substrate in the first region. The step (c) is to form a first silicide protection film on the semiconductor substrate in the first and second regions so as to cover the first and second gate structures. The step (d) is to form a second silicide protection film on the first silicide protection film. The step (e) is to etch and remove the second silicide protection film in the first region using the first suicide protection film as an etching stopper, while leaving the first and second silicide protection films in the second region. The step (f), after the step (e), is to etch and remove the first silicide protection film in the first region, while leaving the first and second silicide protection films in the second region. The step (g), after the step (f), is to form a silicide film on the first and second gate structures and on the semiconductor substrate in the first region.

The first and second silicide protection films are formed in this order on the semiconductor substrate in the second region. That is, a silicide protection film is formed in a two-layered structure. Thus, even when the film thickness of the first silicide protection film is set thin, adjustment of the film thickness of the second silicide protection film can prevent the silicide protection film on the semiconductor substrate in the second region from being completely removed with wet processes usually performed in forming the silicide film. Therefore, even when the distance between the gate structures decreases because of miniaturization of the semiconductor device, the film thickness of the first silicide protection film can be set thin, allowing the first silicide protection film conformal to the underlying shape to be formed. Accordingly, in removing the first silicide protection film, it is possible to reduce the amount that the structure under the first silicide protection film is etched, as compared to the case where the first silicide protection film is not formed conformally to the underlying shape.

Further, the first silicide protection film is used as an etching stopper in etching the second silicide protection film. Thus, even when the film thickness of the second silicide protection film is set so thick as to ensure a sufficient film thickness of the silicide protection film on the semiconductor substrate in the second region, the second silicide protection film can be removed without etching the structure under the second silicide protection film.

Therefore, even when the distance between the gate structures decreases because of miniaturization of the semiconductor device, the silicide protection film on the semiconductor substrate in the first region where the silicide film is to be formed can reliably be removed while suppressing degradation of the semiconductor device in performance, as compared to the case where the silicide protection film is formed in one layer.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 8 are sectional views showing a method of manufacturing a semiconductor device according to a preferred embodiment of the present invention in sequential order of steps;

FIGS. 9 through 12 are sectional views showing a method of manufacturing a conventional semiconductor device in sequential order of steps; and

FIGS. 13 and 14 are views showing drawbacks encountered in the method of manufacturing the conventional semiconductor device.

### DESCRIPTION OF THE PREFERRED EMBODIMENTS

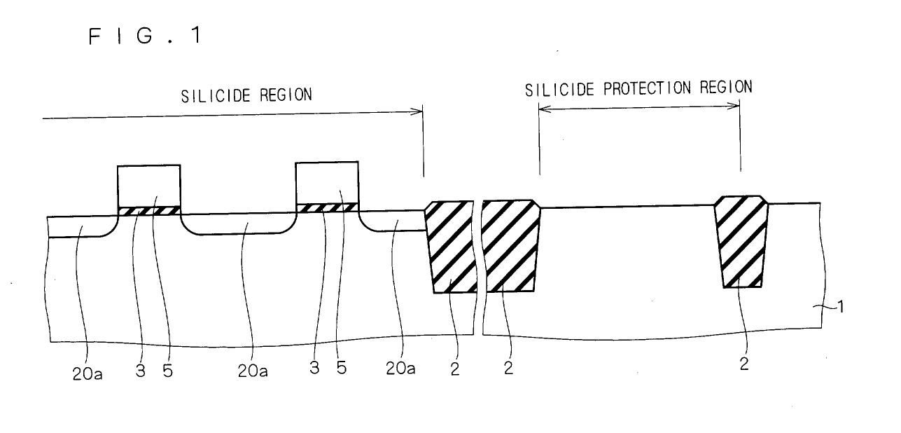

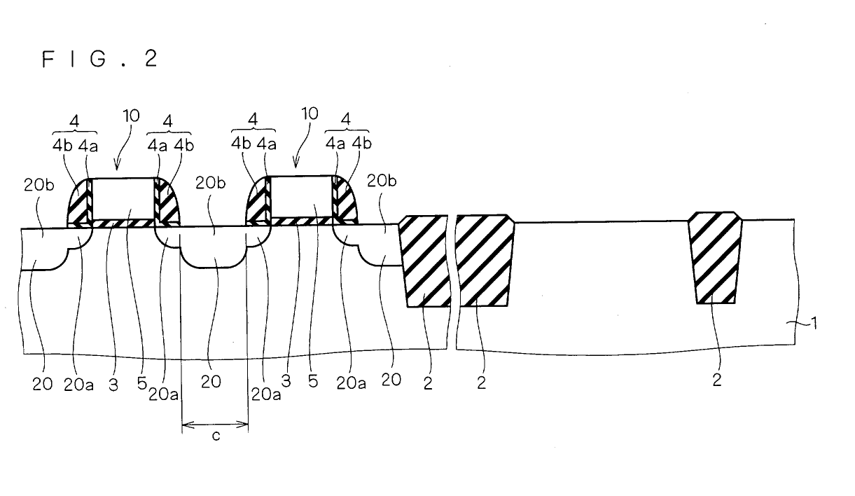

FIGS. 1 through 8 are sectional views showing a method of manufacturing a semiconductor device according to a preferred embodiment of the present invention. First, as shown in FIGS. 1 and 2, an element isolating insulation film 2 is formed in the upper surface of a semiconductor substrate 1, which is a p-type silicon substrate, for example, by well-known LOCOS or trench isolation. The element isolating insulation film 2 is formed of, e.g., a silicon oxide film, and divides the semiconductor substrate 1 into a silicide region on which a silicide film is to be provided and a SP region on which a silicide film is not to be provided. The semiconductor substrate 1 in the SP region is used as a resistor, for example.

Next, a plurality of gate structures 10 are formed at predetermined intervals on the semiconductor substrate 1 in the silicide region. Each gate structure 10 includes a gate insulation film 3 formed of e.g., a silicon oxide film, a gate electrode 5 formed of e.g., a polysilicon film and sidewalls 4. The sidewalls 4 each have a two-layered structure composed of, for example, a TEOS (tetraethyl orthosilicate) film 4a and a silicon nitride film 4b.

A method of forming each gate structure 10 will be described in detail. First, a silicon oxide film and a polysilicon film are formed on the entire surface in this order. Then, a resist having a predetermined opening pattern is provided on the polysilicon film, and the polysilicon film is etched using the resist as a mask until the silicon oxide film is exposed. Accordingly, the gate insulation film 3 and gate electrode 5 are formed in this order on the semiconductor substrate 1 in the silicide region. Impurities such as phosphor or arsenic are ion-implanted at a relatively low concentration into the upper surface of the semiconductor substrate 1 in the silicide region using the gate insulation film 3 and gate electrode 5 as a mask. Accordingly, an n⁻ type impurity region 20a is formed in the upper surface of the semiconductor substrate 1 in the silicide region.

Next, a TEOS film and a silicon nitride film are formed on the entire surface in this order, and are then etched by anisotropic dry etching whose etch rate increases in the depth direction of the semiconductor substrate 1. Accordingly, the sidewalls 4 each including the TEOS film 4a and silicon nitride film 4b are formed on side faces of the gate insulation film 3 and gate electrode 5, whereby formation of the gate structures 10 shown in FIG. 2 is completed. Here, c, the distance between the gate structures 10 is set at 100 nm, for example.

Impurities such as phosphor or arsenic are ion-implanted at a relatively high concentration into the upper surface of the semiconductor substrate 1 in the silicide region using the gate structures 10 as a mask. Accordingly, an n⁺ type impurity region 20b is formed in the upper surface of the semiconductor substrate 1 in the silicide region.

Through the above-described steps, a source/drain region 20 including the n⁻ type impurity region 20a and n⁺ type impurity region 20b is formed in the upper surface of the semiconductor substrate 1 in the silicide region. Accordingly, formation of a plurality of transistors at the semiconductor substrate 1 in the silicide region is completed.

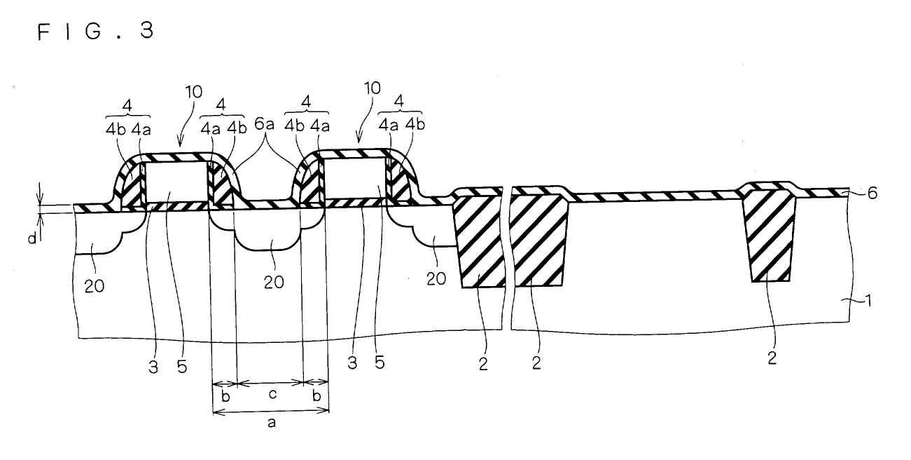

Next, as shown in FIG. 3, a first SP film 6 is formed over the semiconductor substrate 1 in the silicide region and SP region and over the element isolating insulation film 2 so as to cover the gate structures 10. Accordingly, the first SP film 6 is provided on the upper surface of the gate electrode 5, the end portion of the TEOS film 4a and the surface of the silicon nitride film 4b of the sidewall 4. An NSG film, TEOS film or HTO (high temperature heat CVD oxide) film, for example, is used for the first SP film 6.

The film thickness d of the first SP film 6 is set at a value less than half the distance c between the gate structures 10. Specifically, since the plurality of gate structures 10 are formed on the semiconductor substrate 1 in the silicide region, the film thickness d of the first SP film 6 is set at a value less than half the least value among variations in the distance c between the gate structures 10. For instance, at two gate structures 10 adjacent to each other, the distance c between the gate structures 10 takes the value of 100±30 nm in the case where the distance a between a side face of the gate electrode 5 of one of the two gate structures 10 and that of the gate electrode 5 of the other of the two gate structures 10 opposed to each other takes the value of 200±20 nm, and the thickness b of the sidewall 4 of each gate structure 10 takes the value of 50±5 nm. In this case, the film thickness d of the first SP film 6 is set at a value less than 35 nm (35={200−20−2×(50+5)}÷2). In this preferred embodiment, the film thickness d of the first SP film 6 is set at 25 nm, for example. Considering etching of the first SP film 6 at a later step, it is preferable that the film thickness d be as thin as possible.

As described above, setting the film thickness d of the first SP film 6 less than half the distance c between the gate structures 10 allows the first SP film 6 to be conformal to the underlying shape. This is because, at two gate structures 10 adjacent to each other, first SP films 6 provided on sidewalls 4 are not in contact with each other, as shown in FIG. 3.

In the case where the film thickness m (100 nm) of the SP film 106 takes the value not less than half the distance l (100 nm) between the gate structures 110 as in the aforementioned background art, the SP films 106 provided on sidewalls 104 are in contact with each other at two gate structures 110 adjacent to each other, causing the SP film 106 nonconformal to the underlying shape to be formed. In the present embodiment, setting the film thickness d of the first SP film 6 less than half the distance c between the gate structures 10 allows the first SP film 6 to be conformal to the underlying shape.

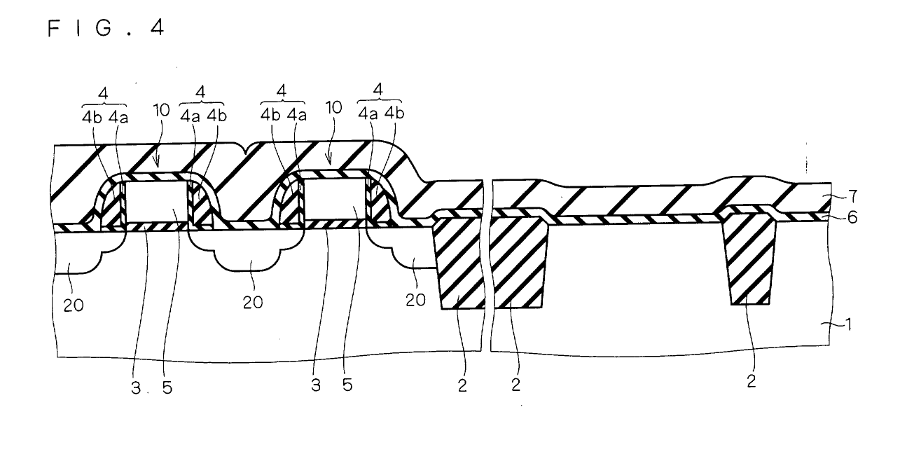

Next, as shown in FIG. 4, a second SP film 7 is formed on the first SP film 6. In the present embodiment, the film thickness of the second SP film 7 is set at 75 nm, for example. This allows the upper surface of the second SP film 7 over the semiconductor substrate 1 in the silicide region to be almost flat. A silicon nitride film or silicon oxynitride film (SiON) formed by a plasma CVD method, silicon nitride film formed by a low-pressure CVD method or the like is used for the second SP film 7. The first SP film 6 and second SP film 7 may be referred to as “SP film 60” in combination.

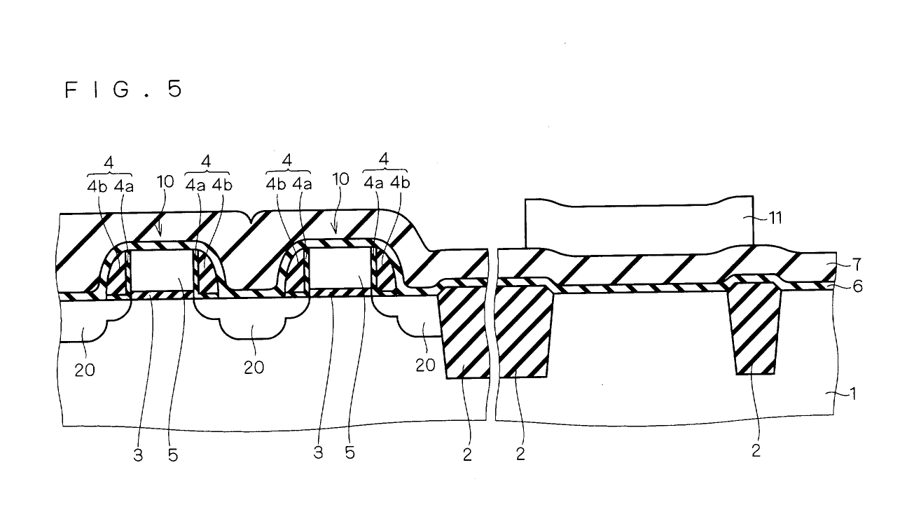

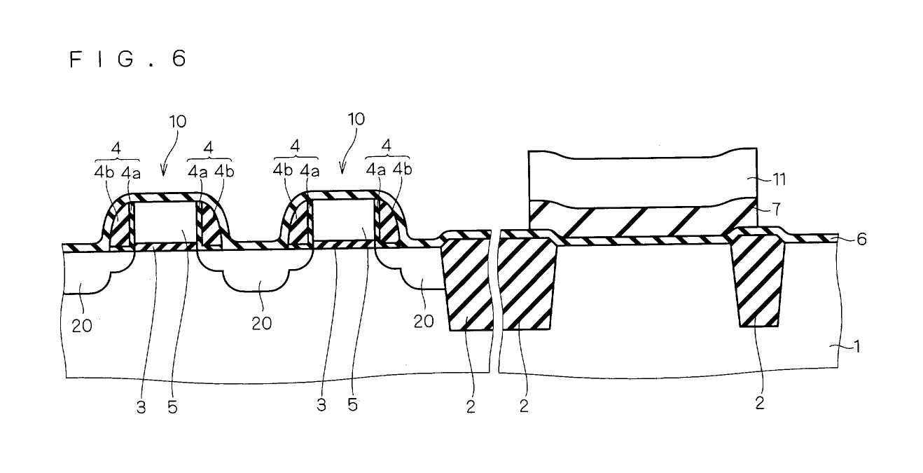

Next, as shown in FIG. 5, a resist 11 is formed on the second SP film 7 in the SP region, while exposing the second SP film 7 present in the silicide region and present on part of the element isolating insulation film 2. Then, as shown in FIG. 6, the second SP film 7 is etched using the resist 11 as a mask. Accordingly, the second SP film 7 present in the silicide region and present above part of the element isolating insulation film 2 is removed, while leaving the first SP film 6 and second SP film 7 in the SP region.

In etching the second SP film 7, an etching method is adopted which has the selectivity to the first SP film 6. For instance, isotropic etching using thermal phosphoric acid is performed for the second SP film 7. Alternatively, such isotropic etching and anisotropic etching such as reactive ion etching may be performed in, combination. Accordingly, the first SP film 6 serves as an etching stopper. The selectivity to the first SP film 6 at this time is preferably 4 to 5.

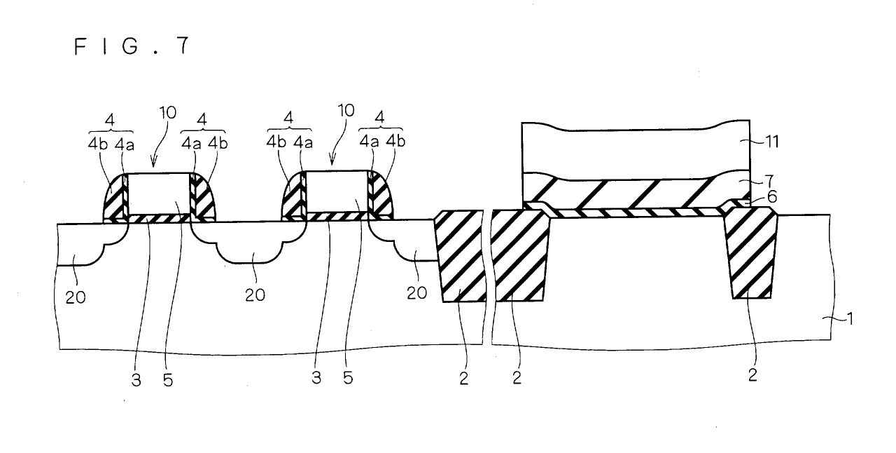

Next, as shown in FIG. 7, the first SP film 6 is etched using the resist 11 again as a mask. Accordingly, the first SP film 6 present in the silicide region and present on part of the element isolating insulation film 2 is removed, while leaving the first SP film 6 and second SP film 7 in the SP region.

In etching the first SP film 6, an etching method is adopted which has the selectivity to the semiconductor substrate 1, gate electrode 5, silicon nitride film 4b of the sidewall 4. For instance, isotropic etching using hydrofluoric acid is performed for the first SP film 6.

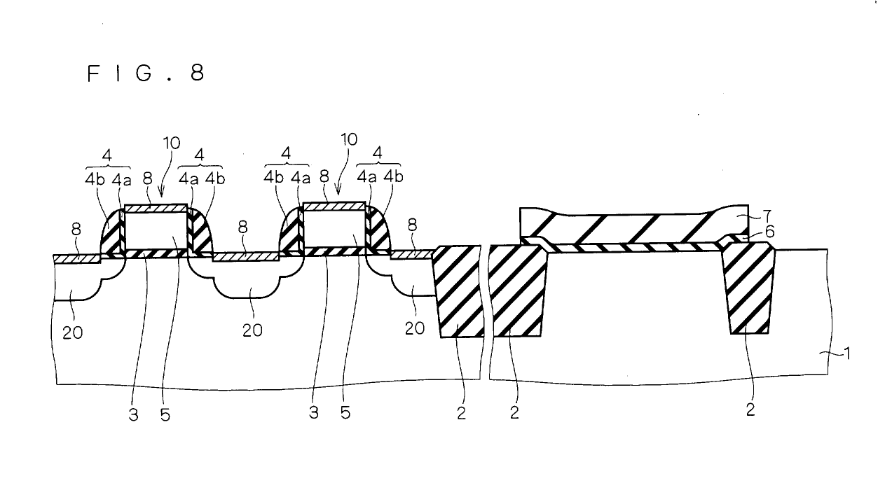

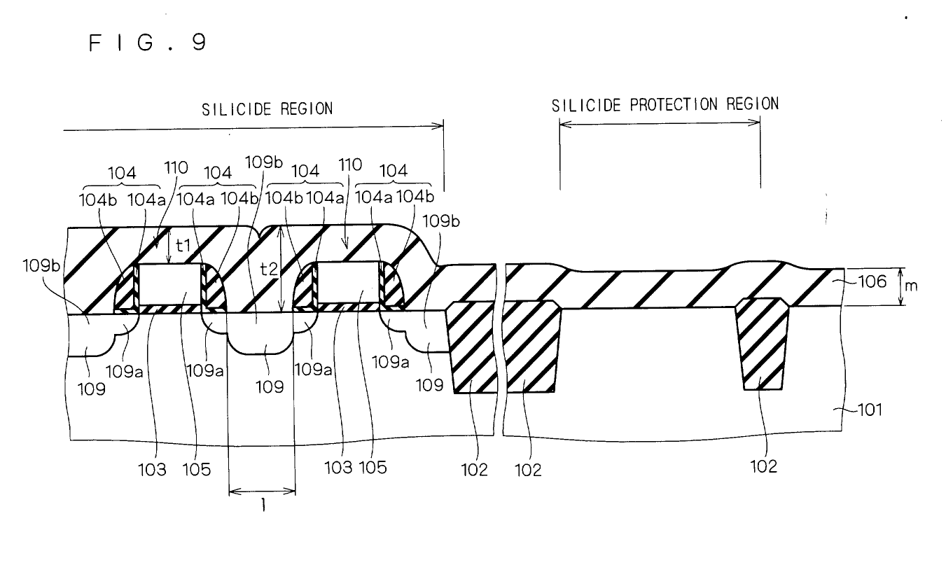

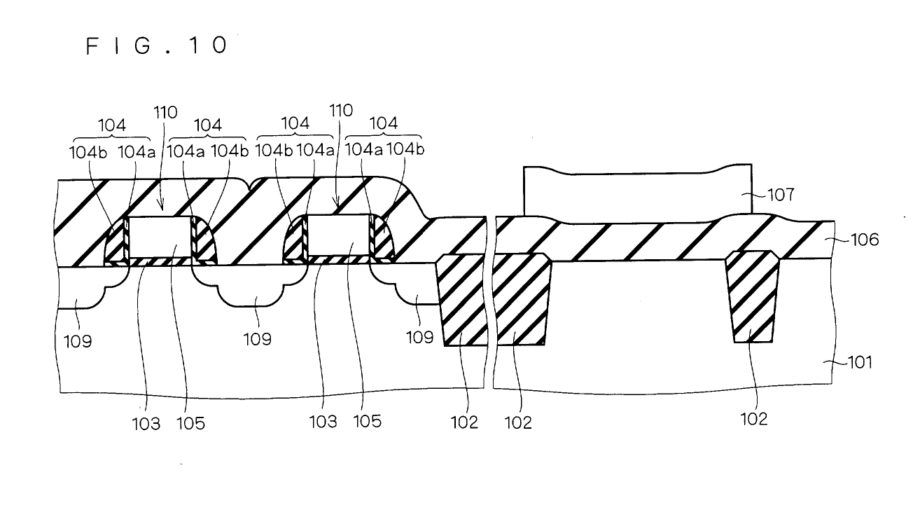

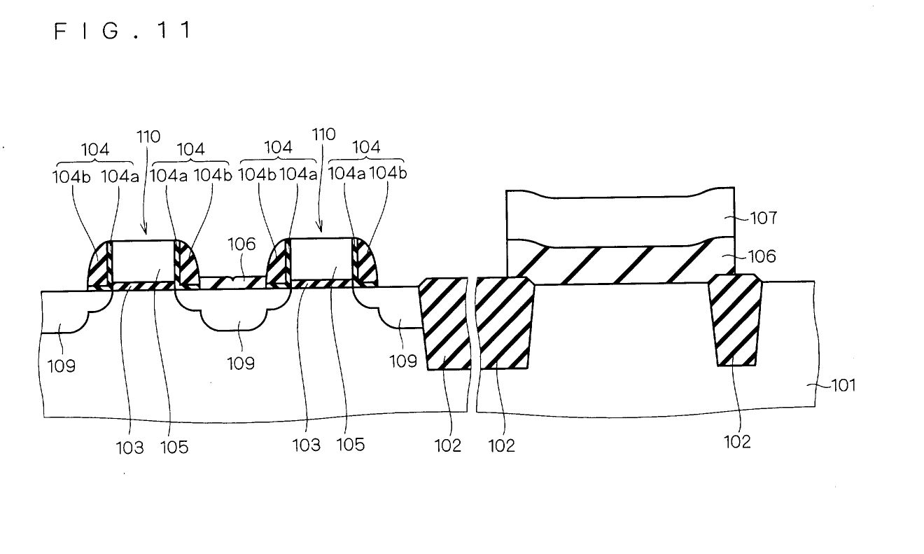

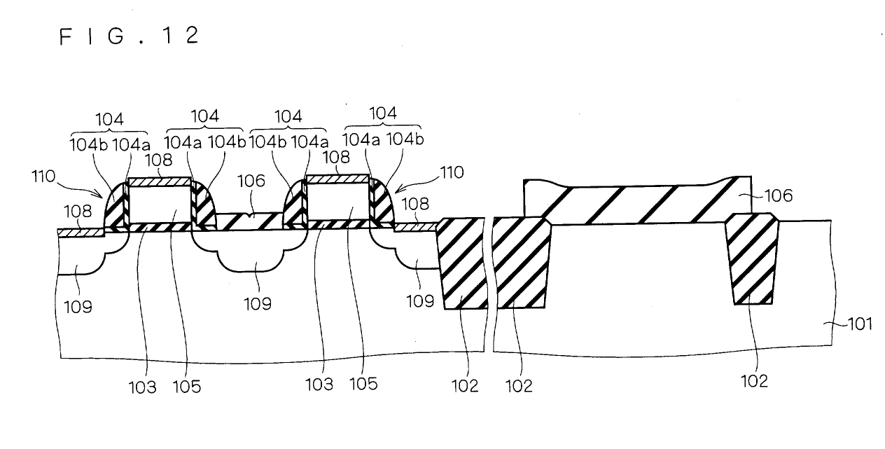

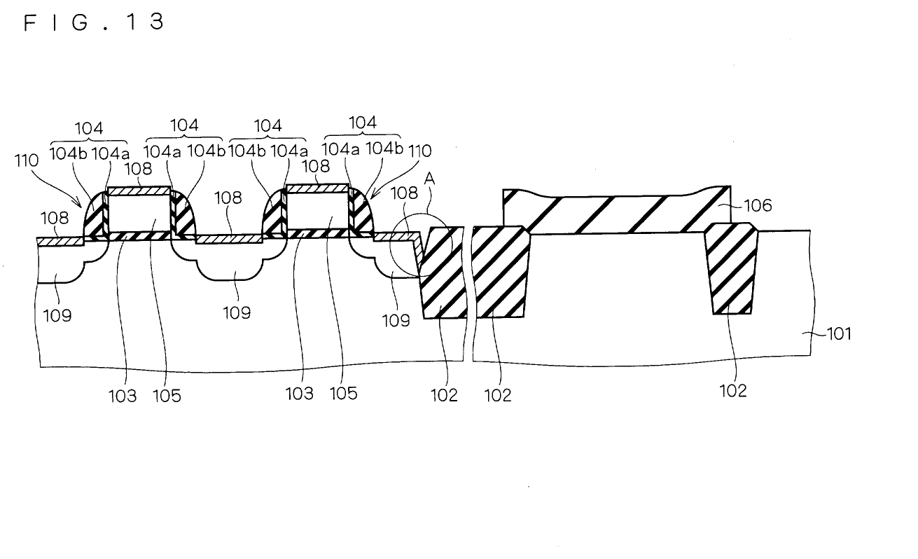

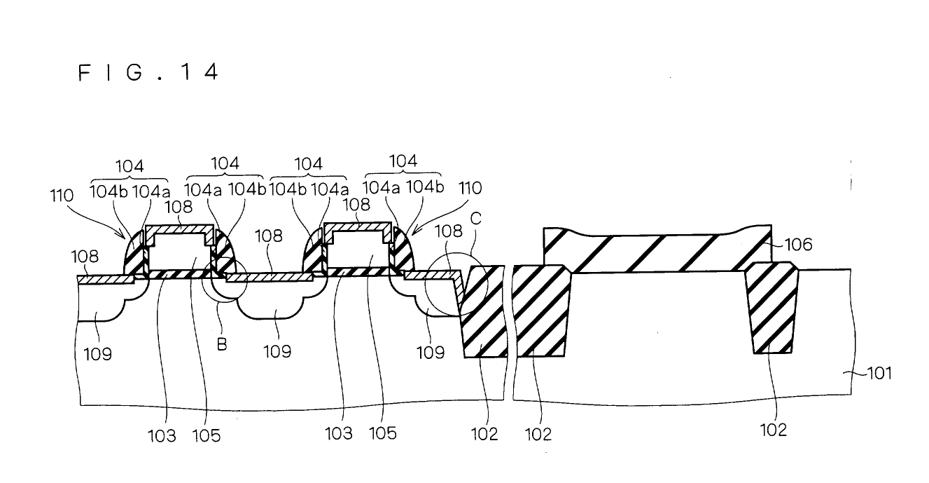

Next, the resist 11 is removed to implement salicidation. Specifically, a cobalt film is formed on the entire surface by sputtering, for example. Then, heat treatment is conducted using a lamp anneal system, for example, to cause cobalt to react with silicon in contact therewith. Accordingly, the upper surface of the semiconductor substrate 1 in the silicide region that has been exposed before the cobalt film is formed is silicided, whereby a silicide film 8 is formed. At the same time, the upper surface of the gate electrode 5 of each gate structure 10 is silicided, whereby the silicide film 8 is formed. Thereafter, an unreacted part of the cobalt film is removed, thereby obtaining the structure shown in FIG. 8. Since the SP film 60 is formed on the semiconductor substrate 1 in the SP region, silicidation is not performed, and hence, the silicide film 8 is not formed on the semiconductor substrate 1 in the SP region. In forming the silicide film 8, a plurality of wet processes are usually performed.

As described above, according to the method of the present embodiment, the SP film 60 is formed in a two-layered structure on the semiconductor substrate 1 in the SP region. Thus, even when the film thickness of the first SP film 6 is set thin, adjustment of the film thickness of the second SP film 7 can prevent the SP film 60 on the semiconductor substrate 1 in the SP region from being completely removed with wet processes usually performed in forming the silicide film 8. Therefore, even when the distance c between the gate structures 10 decreases because of miniaturization of the semiconductor device, the film thickness d of the first SP film 6 can be set thin, allowing the first SP film 6 conformal to the underlying shape to be formed, as described in the present embodiment. Accordingly, the thickness of the first SP film 6 on the gate structures 10 and that on the semiconductor substrate 1 between the gate structures 10 become almost the same. As a result, in removing the first SP film 6, it is possible to reduce the amount that the structure under the first SP film 6, e.g., the gate electrode 5 and the like are etched, as compared to the case where the first SP film 6 is not formed conformally to the underlying shape as in the aforementioned background art.

Further, in this embodiment, the first SP film 6 is used as an etching stopper in etching the second SP film 7. Thus, even when the film thickness of the second SP film 7 is set so thick as to ensure a sufficient film thickness of the SP film 60 on the semiconductor substrate 1 in the SP region, causing the upper surface of the second SP film 7 in the silicide region to be almost flat, that is, when the thickness of the second SP film 7 over the semiconductor substrate 1 between the gate structures 10 is greater than that over the gate structures 10, the second SP film 7 can be removed without etching the structure under the second SP film 7, e.g., the gate structures 10 and the like.

Therefore, according to the method of this embodiment, the SP film 60 on the semiconductor substrate 1 in the silicide region where the silicide film 8 is to be formed can reliably be removed while suppressing degradation of the semiconductor device in performance even when the distance between the gate structures 10 decreases because of miniaturization of the semiconductor device, as compared to the aforementioned background art in which the SP film is formed in one layer.

Further, as in the present embodiment, forming the first SP film 6 conformally to the underlying shape allows a reduction of the amount that the TEOS film 4a is etched in removing the first SP film 6, even when the sidewall 4 which is basically not desired to be etched includes the TEOS film 4a having no selectivity to the first SP film 6. As a result, it is possible to reduce the amount that the silicide film 8 is formed below the silicon nitride film 4b of the sidewall 4, which can suppress degradation of transistor characteristics.

Furthermore, as in the present embodiment, forming the first SP film 6 conformally to the underlying shape allows a reduction of the amount that the element isolating insulation film 2 is etched in removing the first SP film 6, even when the element isolating insulation film 2 has no selectivity to the first SP film 6. As a result, it is possible to suppress degradation of the semiconductor device in junction leak characteristic.

Although the present embodiment has described the case where the gate structures 10 each have sidewalls 4, the gate structures 10 may not be provided with the sidewalls 4. In that case, the distance c between the gate structures 10 is the distance between a side face of the gate electrode 5 of one of two gate structures 10 adjacent to each other and a side face of the gate electrode 5 of the other of the two gate structures 10.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device, comprising the steps of:
(a) preparing a semiconductor substrate having first and second regions;
(b) forming first and second gate structures at a predetermined interval therebetween on said semiconductor substrate in said first region;
(c) forming a first silicide protection film on said semiconductor substrate in said first and second regions so as to cover said first and second gate structures;
(d) forming a second silicide protection film on said first silicide protection film;
(e) etching and removing said second silicide protection film in said first region using said first silicide protection film as an etching stopper, while leaving said first and second silicide protection films in said second region;
(f) after said step (e), etching and removing said first silicide protection film in said first region, while leaving said first and second silicide protection films in said second region; and
(g) after said step (f), forming a silicide film on said first and second gate structures and on said semiconductor substrate in said first region.

2. The method according to claim 1, wherein
in said step (c), said first silicide protection film is set to have a film thickness less than half the distance between a side face of said first gate structure and a side face of said second gate structure opposed to each other.

3. The method according to claim 2, wherein
said first and second gate structures each have a gate electrode and a sidewall provided on a side face of said gate electrode, and
in said step (c), said first silicide protection film is set to have a film thickness less than half the distance between a surface of said sidewall of said first gate structure and a surface of said sidewall of said second gate structure opposed to each other.

4. The method according to claim 3, wherein
said sidewall includes a first film provided on said side face of said gate electrode and a second film provided on said first film, and
in said step (c), said first silicide protection film is also formed on said first and second films of said sidewall.

5. The method according to claim 2, wherein
an element isolating insulation film is formed in an upper surface of said semiconductor substrate prepared in said step (a) for dividing said first and second regions,
in said step (c), said first silicide protection film is also formed on said element isolating insulation film,
in said step (e), said second silicide protection film above said element isolating insulation film is also etched and removed, and
in said step (f), said first silicide protection film on said element isolating insulation film is also etched and removed.

6. The method according to claim 3, wherein
an element isolating insulation film is formed in an upper surface of said semiconductor substrate prepared in said step (a) for dividing said first and second regions,
in said step (c), said first silicide protection film is also formed on said element isolating insulation film,
in said step (e), said second silicide protection film above said element isolating insulation film is also etched and removed, and
in said step (f), said first silicide protection film on said element isolating insulation film is also etched and removed.

7. The method according to claim 4, wherein
an element isolating insulation film is formed in an upper surface of said semiconductor substrate prepared in said step (a) for dividing said first and second regions,
in said step (c), said first silicide protection film is also formed on said element isolating insulation film,
in said step (e), said second silicide protection film above said element isolating insulation film is also etched and removed, and
in said step (f), said first silicide protection film on said element isolating insulation film is also etched and removed.
